(19) United States
(12) Patent Application Publication
(10) Pub. No.: US 2017/0335459 A1
(43) Pub. Date: Nov. 23, 2017

(54) NON-SHADOW FRAME PLASMA PROCESSING CHAMBER

(71) Applicant: Applied Materials, Inc., Santa Clara, CA (US)

(72) Inventors: Young-jin CHOI, San Jose, CA (US); Beom Soo PARK, San Jose, CA (US); Dongsuh LEE, Gilroy, CA (US); William Norman STERLING, Santa Clara, CA (US); Robin L. TINER, Santa Cruz, CA (US); Shinichi KURITA, San Jose, CA (US); Suhail ANWAR, Saratoga, CA (US); Soo Young CHOI, Fremont, CA (US); Yi CUI, San Jose, CA (US); Lia ZHAO, Campbell, CA (US); Dapeng WANG, San Jose, CA (US)

(21) Appl. No.: 15/157,076

(22) Filed: May 17, 2016

(51) Int. Cl. C23C 16/50; C23C 16/40; C23C 16/458; H01L 21/687; H01L 21/285; H01L 21/02

(52) U.S. Cl. CPC C23C 16/50; C23C 16/4583; H01L 21/68757; H01L 21/68785; C23C 16/402; H01L 21/02274; H01L 21/28556; H01L 21/0262

(57) ABSTRACT

Embodiments described herein generally relate to a substrate support assembly. The substrate support assembly includes a support plate and a ceramic layer. The support plate has a top surface. The top surface includes a substrate receiving area configured to support a large area substrate and an outer area located outward of the substrate receiving area.

### BACKGROUND

### Field

Embodiments described herein generally relate to a substrate support assembly.

### Description of the Related Art

Flat panel displays (FPD) are commonly used for active matrix displays such as computer and television monitors, personal digital assistants (PDAs), and cell phones, as well as solar cells and the like. Plasma enhanced chemical vapor deposition (PECVD) may be employed in flat panel display fabrication to deposit thin film on a substrate. PECVD is generally accomplished by executing a precursor gas into a plasma within a vacuum process chamber and depositing a film on a substrate from the excited precursor gas.

Conventional PECVD systems use a shadow frame to hold the substrate during processing. The shadow frame has the tendency to degrade film thickness uniformity around the edge of the substrate. At the same time, if the shadow frame is not used, plasma arcing may occur on the support plate.

Thus, there is a need for an improved substrate support assembly.

### SUMMARY

Embodiments described herein generally relate to a substrate support assembly. The substrate support assembly includes a support plate having an ex-situ deposited ceramic layer. The support plate has a top surface. The top surface includes a substrate receiving area configured to support a large area substrate and an outer area located outward of the substrate receiving area. The ceramic layer is disposed on at least the outer area.

In another embodiment, a processing chamber is disclosed herein. The processing chamber includes a chamber body and a substrate support assembly. The chamber body includes a top wall, a sidewall, and a bottom wall defining a processing region in the chamber body. The substrate support assembly is disposed in the processing region. The substrate support assembly includes a support plate having an ex-situ deposited ceramic layer. The support plate has a top surface. The top surface includes a substrate receiving area configured to support a large area substrate and an outer area located outward of the substrate receiving area. The ceramic layer is disposed on at least the outer area.

In another embodiment, a method of processing a substrate in a plasma enhanced chemical vapor deposition chamber is disclosed herein. The method includes positioning a large area substrate on a top surface of a support plate disposed in the deposition chamber, the top surface having a substrate receiving area and an outer area outward of the substrate receiving area, the outer area having an ex-situ deposited ceramic layer. The method further includes performing a plasma enhanced chemical vapor deposition process to deposit a layer of material on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional view of a processing chamber having a substrate support assembly disposed therein, according to one embodiment.

FIG. 2 illustrates a cross-sectional view of a portion of the substrate support assembly of FIG. 1, according to one embodiment.

FIG. 3 illustrates a top view of the substrate support assembly of FIG. 2, according to one embodiment.

For clarity, identical reference numerals have been used, where applicable, to designate identical elements that are common between figures. Additionally, elements of one embodiment may be advantageously adapted for utilization in other embodiments described herein.

### DETAILED DESCRIPTION

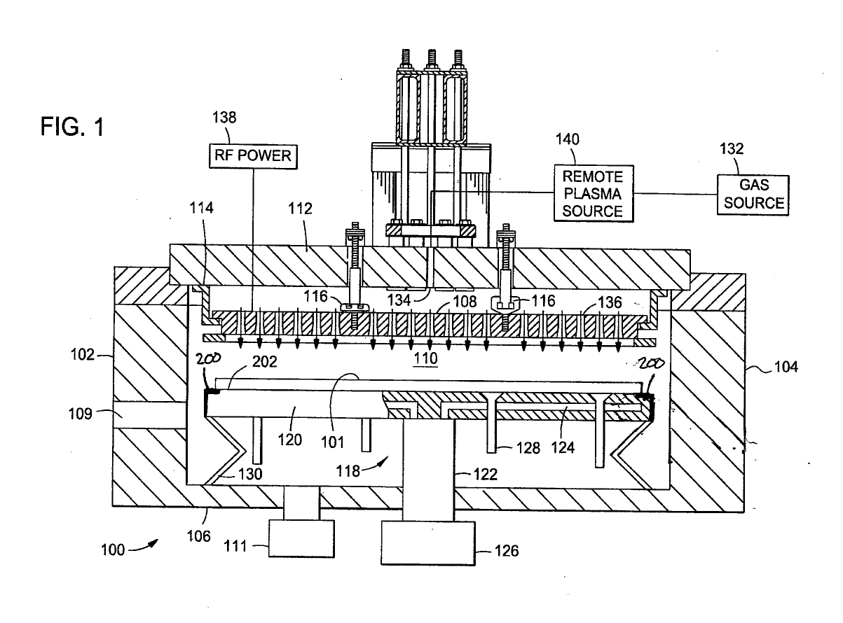

FIG. 1 illustrates a cross-sectional view of a processing chamber 100 having a substrate support assembly 118 with a ceramic layer 200 deposited thereon, according to one embodiment. The processing chamber 100 may include a chamber body 102 having sidewalls 104, and a bottom 106 that define a processing volume 110. The processing volume 110 is accessed through an opening 109 formed through the sidewalls 104.

A showerhead 108 is disposed in the processing volume 110. The showerhead 108 may be coupled to a backing plate 112. For example, the showerhead 108 may be coupled to the backing plate 112 by a suspension 114 at the end of the backing plate 112. One or more coupling supports 116 may be used to couple the showerhead 108 to the backing plate 112 to aid in preventing sag.

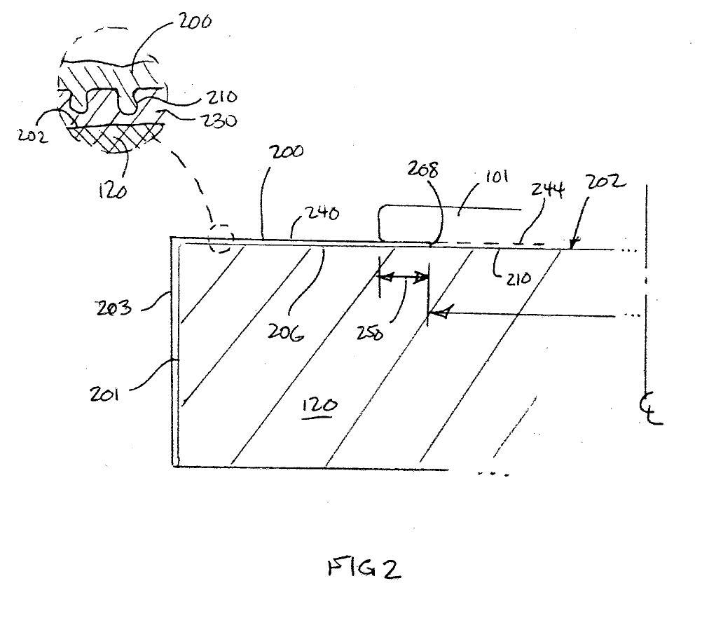

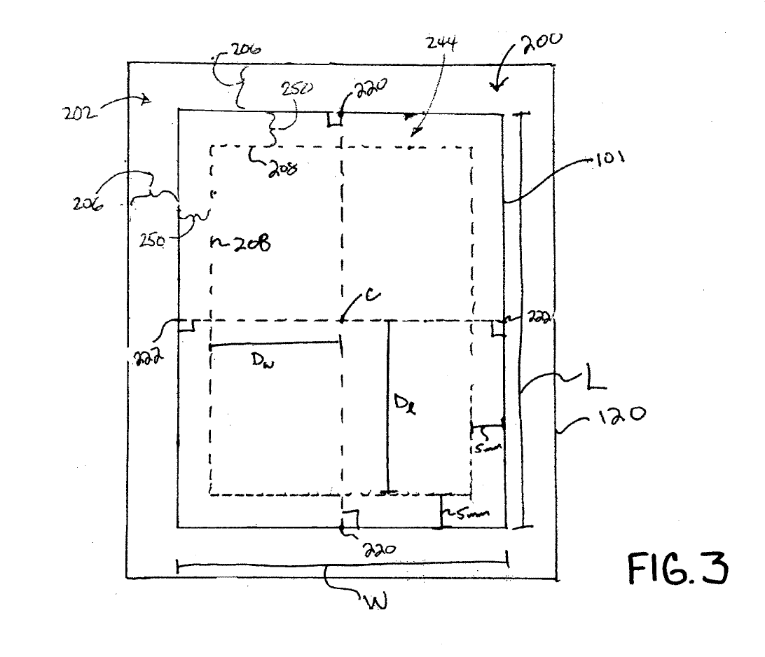

The substrate support assembly 118 is also disposed in the processing volume 110. The substrate support assembly 118 includes a support plate 120, a ceramic layer 200, and a stem 122 coupled to the support plate 120. The support plate 120 is configured to support a substrate 101 during processing. In one embodiment, the support plate 120 may be formed from a metal, such as aluminum. Portions or all of the support plate 120 are anodized. The ceramic layer 200 (discussed in detail in FIGS. 2-3) is deposited on the support plate 120 prior to installation and use in the processing chamber 100, in other words, the ceramic layer 200 is deposited ex-situ the processing chamber 100. The ceramic layer 200 is configured to prevent plasma arcing of the support plate 120 during processing. Further details of the ex-situ deposited ceramic layer 200 are provided further below with reference to FIGS. 2-3.

Continuing to refer to FIG. 1, the support plate 120 includes temperature control elements 124. The temperature control elements 124 are configured to maintain the substrate support assembly 118 at a desired temperature. The temperature control elements 124 run up through the stem 122 and extend throughout a full-area of the support plate 120.

A lift system 126 may be coupled to the stem 122 to raise and lower the support plate 120. Lift pins 128 are moveably disposed through the support plate 120 to space the substrate 101 from the support plate 120 to facilitate robotic transfer of the substrate 101. The substrate support assembly 118 may also include RF return straps 130 to provide an RF return path at an end of the substrate support assembly 118.

A gas source 132 may be coupled to the backing plate 112 to provide processing gas through a gas outlet 134 in the backing plate 112. The processing gas flows from the gas outlet 134 through gas passages 136 in the showerhead 108. A vacuum pump 111 may be coupled to the chamber 100 to control the pressure within the processing volume 110. An RF power source 138 may be coupled to the backing plate 112 and/or to the showerhead 108 to provide RF power to the showerhead 108. The RF power creates an electric field between the showerhead 108 and the substrate support assembly 118 so that a plasma may be generated from the gases between the showerhead 108 and the substrate support assembly 118.

A remote plasma source 140, such as an inductively coupled remote plasma source, may also be coupled between the gas source 132 and the backing plate 112. Between processing substrates, a cleaning gas may be provided to the remote plasma source 140 so that a remote plasma is generated and provided into the processing volume 110 to clean chamber components. The cleaning gas may be further excited while in the processing volume 110 by power applied to the showerhead 108 from the RF power source 138. Suitable cleaning gases include but are not limited to NF₃, F₂, and SF₆.

Conventional PECVD systems utilize a shadow frame positioned about a periphery of the substrate to prevent process gases or plasma from reaching the edge and the backside of the substrate, thus preventing plasma arcing of the surface of the support plate and preventing deposition on the extreme end and backside of the substrate. To increase the area available for deposition, the shadow fram is not utilized herein. With the absence of the shadow frame, the ex-situ deposited ceramic layer 200 protects the exposed portion of the top surface of the support plate 120 from arcing and plasma attack.

FIGS. 2 and 3 illustrate the substrate support assembly 118, according to one embodiment illustrating the ex-situ deposited ceramic layer 200 disposed on at least a top surface anodized layer 230 of the support plate 120. The ceramic layer 200 is configured to provide an insulated surface to prevent plasma arcing of the support plate 120. The support plate 120 generally includes a top surface 202. The top surface 202 includes a substrate receiving surface 244 and an outer area 206. The substrate receiving surface 244 is configured to receive the substrate 101. The outer area 206 is exterior to the substrate receiving surface 244. Generally, the outer area 206 is free from the substrate 101.

The ceramic layer 200 includes a first portion 240 selectively deposited on the top surface and a second portion 203 deposited on a side of the support plate 120. The ceramic layer 200 may be formed on at least the outer area 206 and partially onto the substrate receiving surface 244. In one embodiment, a surface area of the top surface 202, which is covered by the ceramic layer 200, is greater than a surface area of the outer area 206. When the ceramic layer 200 is deposited partially onto the substrate receiving surface 244, the ceramic layer 200 extends partially beneath the substrate 101 creating an overlap area 250. In one embodiment, the ceramic layer 200 may extends at least 5 mm onto the substrate receiving surface 244. In another embodiment, the ceramic layer 200 may extend a full surface of the top surface 202.

In general, the substrate receiving surface 244 may have dimensions l×w, where l can be less than or equal to w. An inner edge 208 of the ceramic layer 200 may be disposed at least a distance, D_{w} from a center, C, of the support plate 120 in the width direction, and at least a distance Dₗ, from the center, C, in the length direction. Because all points along a perimeter of a rectangle are not equidistant to a center of the rectangle, D_{w} and Dₗ are computed with respect to a midpoint 220 of the length of the substrate receiving surface 244 and a midpoint 222 of the width of the substrate receiving surface. Generally the dimensions of the substrate receiving surface 244 are the dimensions of the substrate to be processed.

For example, Dₗ may be represented by:

$${D}_{l} = \frac{l}{2} - 5$$

where l represents the length of the substrate receiving surface 244 in millimeters.

For example, D_{w} may be represented by:

$${D}_{w} = \frac{w}{2} - 5$$

where w represents the length of the substrate receiving surface 244 in millimeters.

For example, given a substrate having a dimension of 400 mm×500 (l×w) mm, the inner edge 208 of the ceramic layer is disposed

$${D}_{l} = \frac{400}{2} - 5 = 195 mm$$

in the l direction. The inner edge 208 of the ceramic layer is disposed:

$${D}_{w} = \frac{500}{2} - 5 = 245 mm$$

in the w direction.

For example, given a substrate having a dimension of 1870 mm×2200 (l×w) mm, the inner edge 208 of the ceramic layer is disposed

$${D}_{l} = \frac{1870}{2} - 5 = 930 mm$$

in the l direction from the center of the support plate 120. The inner edge 208 of the ceramic layer is disposed:

$${D}_{w} = \frac{500}{2} - 5 = 1095 mm$$

in the w direction from the center of the support plate 120.

For example, given a substrate having a dimension of 2880 mm×3130 (l×w) mm, the inner edge 208 of the ceramic layer is disposed

$${D}_{l} = \frac{2880}{2} - 5 = 1435 mm$$

in the l direction from the center of the support plate 120. The inner edge 208 of the ceramic layer 200 is disposed:

$${D}_{w} = \frac{3130}{2} - 5 = 1560 mm$$

in the w direction from the center of the support plate 120.

In one embodiment, the ceramic layer 200 may be deposited on the support plate 120 ex-situ using an arc spray deposition technique. In another embodiment, the ceramic layer 200 may be deposited on the support plate 120 ex-situ using a physical vapor deposition (PVD) sputtering technique.

The top surface 202 may include an anodized layer 230 having an initial surface roughness of between about 80-230 pinches formed from a plurality of pores 210. The anodized layer 230 may be bead blasted before the ceramic layer 200 is deposited on the support plate 120 ex-situ. The surface roughness of the anodized layer 230 decreases to about 80-200 pinches after bead blasting. When the support plate 120 is coated ex-situ, the ceramic layer 200 is also deposited into the pores 210. In one embodiment, the resulting surface roughness of the support plate 120 having the ceramic layer deposited thereon is about 2-10 μm. In another embodiment, the ceramic layer 200 has a porosity between about 3% and 10%. In another embodiment, the ceramic layer 200 has a uniformity between about 5% to 20%.

The ceramic layer 200 may have a thickness such that the ceramic layer 200 prevents plasma arcing of the support plate 120 while not decreasing plasma density at the edge of the substrate 101. For example, the ceramic layer 200 having a thickness between 10-15 μm is sufficient to prevent plasma arcing of the support plate 120 while not being too thick as to cause a decreased plasma density at the edge of the substrate 101.

In another embodiment, the ceramic layer 200 has a thickness such that the ceramic layer 200 has a breakdown voltage of at least 500 V. For example, the ceramic layer 200 has a thickness such that the ceramic layer 200 has a breakdown voltage between 1000-2000 V. In another example, the ceramic layer 200 has a thickness such that the ceramic layer 200 has a dielectric constant between about 3 to about 10 with a frequency of about 10³ Hz. In another embodiment, the ceramic layer 200 has a dielectric constant between about 5 to about 40 with a frequency between about 10⁴ Hz and 10⁶ Hz.

The ceramic layer 200 may be formed from an insulation material. In one embodiment, the ceramic layer 200 may be formed from SiO₂. In another embodiment, the ceramic layer 200 may be formed from Al₂O₃. Generally, the ceramic layer 200 may be made of a material and have a thickness such that the ceramic layer 200 can withstand a cleaning process at elevated temperatures using fluorine gases. For example, the ceramic layer 200 may have a peel strength of 1,000-2,000 pounds per square inch (psi). In another example, the ceramic layer 200 may have a hardness between about 500 Vickers Pyramid Number (HV) and about 1000 HV.

In operation, a large area substrate is positioned on a top surface of a support plate disposed in the deposition chamber. The support plate has a substrate receiving area and an outer area outward of the substrate receiving area. The outer area having an ex-situ deposited ceramic later. A plasma enhanced chemical vapor deposition process is performed on the substrate to deposit a layer of material on the substrate.

As recited above, the ceramic layer 200 prevents plasma arcing of the support plate 120 during plasma processing. The ceramic layer 200 prevents plasma arcing while enhancing deposition uniformity of the substrate. Thus, the ceramic layer 200 allows a processing alternative without use of a shadow frame, thereby advantageously increasing the area of the substrate available for device fabrication.

While the foregoing is directed to specific embodiments, other and further embodiments may be devised without departing from the basic scope thereof, and the scope thereof is determined by the claims that follow.

What is claimed is:

1. A substrate support assembly, comprising:
a support plate having a top surface, the top surface comprising a substrate receiving area configured to support a large area substrate and an outer area located outward of the substrate receiving area; and
an ex-situ deposited ceramic layer deposited on the outer area of the top surface of the support plate.

2. The substrate support assembly of claim 1, wherein the ceramic layer has a thickness between 10-15 μm.

3. The substrate support assembly of claim 1, wherein the ceramic layer is formed from one of SiO₂ and Al₂O₃.

4. The substrate support assembly of claim 1, wherein the ceramic layer is deposited on a full area of the substrate receiving area.

5. The substrate support assembly of claim 1, wherein the ceramic layer has an inner edge that is positioned at least distance equal to half a length of the substrate receiving area less 5 mm.

6. The substrate support assembly of claim 1, wherein the ceramic layer has a thickness such that the ceramic layer has a breakdown voltage between 500-2000 V.

7. The substrate support assembly of claim 1, wherein the ceramic layer covers a side of the support plate.

8. The substrate support assembly of claim 1, wherein the surface of the support plate is anodized and the ceramic layer covers a roughened portion of the anodized top surface.

9. The substrate support assembly of claim 1, wherein the ceramic layer is arc-spray deposited.

10. A processing chamber, comprising:
a chamber body comprising a top wall, a sidewall and a bottom wall defining a processing region in the chamber body; and
a substrate support assembly disposed in the processing region, the substrate support assembly comprising:
a support plate having a top surface, the top surface comprising a substrate receiving area configured to support a large area substrate and an outer area located outward of the substrate receiving area; and
an ex-situ deposited ceramic layer deposited on the outer area of the top surface of the support plate.

11. The processing chamber of claim 10, wherein the ceramic layer has a thickness between 10-15 μm.

12. The processing chamber of claim 10, wherein the ceramic layer is formed from one of SiO₂ and Al₂O₃.

13. The processing chamber of claim 10, wherein the ceramic layer is deposited on a full area of the substrate receiving area.

14. The processing chamber of claim 10, wherein the ceramic layer has a thickness such that the ceramic layer has a breakdown voltage between 500-2000 V.

15. The processing chamber of claim 10, wherein the ceramic layer covers a side of the support plate.

16. The processing chamber of claim 10, wherein the ceramic layer has an inner edge that is positioned at least distance equal to half a length of the substrate receiving area less 5 mm.

17. The processing chamber of claim 10, wherein the surface of the support plate is anodized and the ceramic layer covers a roughened portion of the anodized top surface.

18. The processing chamber of claim 10, wherein the ceramic layer is arc-spray deposited.

19. A method of processing a substrate comprising:
positioning the substrate on a support plate having a substrate receiving area and an outer area outward of the substrate receiving area, the outer area having an ex-situ deposited ceramic; and
performing a plasma enhanced chemical vapor deposition process to deposit a layer of material on the substrate.

20. The method of claim 19, wherein the ceramic layer is formed from SiO₂ and has a thickness between 10-15 μm.
